(19) United States
(12) Patent Application Publication
(10) Pub. No.: US 2026/0033362 A1
(43) Pub. Date: Jan. 29, 2026

(54) PACKAGE SUBSTRATE AND SEMICONDUCTOR PACKAGE

(71) Applicant: Samsung Electronics Co., Ltd., Suwon-si (KR)

(72) Inventors: Minji Park, Suwon-si (KR); Sangkeun Kwak, Suwon-si (KR); Dongyeop Kim, Suwon-si (KR); Seungjin Lee, Suwon-si (KR)

(21) Appl. No.: 19/019,583

(22) Filed: Jan. 14, 2025

(30) Foreign Application Priority Data
Jul. 25, 2024 (KR) 10-2024-0098758

(51) Int. Cl. H01L 23/538; H01L 23/498

(52) U.S. Cl. CPC H01L 23/5386; H01L 23/49894; H01L 23/5383

(57) ABSTRACT

A package substrate includes a plurality of layers, each layer of the plurality of layers including a respective conductive pattern. The plurality of layers includes a first layer in which a first conductive pattern and a plurality of pads exposed externally with respect to the package substrate are disposed, a second layer located above the first layer, and including a second conductive pattern and a floating wiring pattern having an area overlapping the plurality of pads, and a third layer located above the second layer, and including a third conductive pattern.

### CROSS-REFERENCE TO RELATED APPLICATION(S)

This application claims the benefit under 35 U.S.C. § 119(a) of Korean Patent Application No. 10-2024-0098758 filed on Jul. 25, 2024, in the Korean Intellectual Property Office, the entire disclosure of which is incorporated herein by reference for all purposes.

### BACKGROUND

The present inventive concept relates to a package substrate and a semiconductor package.

Crosstalk noise is a phenomenon caused by electromagnetic coupling between signal wiring patterns. Crosstalk noise generates timing jitter when transmitting high-capacity and/or high-speed signals, and is a limiting factor in improving signal quality and signal transmission speed. Recently, research has been actively undertaken to compensate for crosstalk noise in package substrates and semiconductor packages including various semiconductor chips such as Dynamic Random Access Memory (DRAM) and Compression Attached Memory Module (CAMM).

### SUMMARY

Example embodiments provide a package substrate and a semiconductor package including the same, in which signal characteristics may be improved by compensating for inductance and reducing crosstalk noise by intentionally adding capacitance to a wiring pattern in which the influence of inductance is dominant.

According to some example embodiments, a package substrate includes a plurality of layers, each layer of the plurality of layers including a corresponding conductive pattern. Each layer may also include a base layer. The plurality of layers includes a first layer in which a first conductive pattern and a plurality of pads exposed externally with respect to the package substrate are disposed, a second layer located above the first layer, and including a second conductive pattern and a floating wiring pattern having an area overlapping the plurality of pads, and a third layer located above the second layer, and including a third conductive pattern.

According to some example embodiments, a semiconductor package includes a main board, a package substrate, semiconductor chips mounted on the package substrate, and a connector connecting the main board to the package substrate. The package substrate includes a plurality of layers, each layer of the plurality of layers including a corresponding conductive pattern. Each layer may also include a base layer. The plurality of layers includes a first layer in which a first conductive pattern and a plurality of pads exposed externally with respect to the package substrate are disposed, a second layer located above the first layer and including a second conductive pattern and a floating wiring pattern having an area overlapping the plurality of pads, and a third layer located above the second layer and including a third conductive pattern.

According to some example embodiments, a package substrate includes a plurality of layers, each layer of the plurality of layers including a corresponding conductive pattern. Each layer may also include a base layer. The plurality of layers includes a first layer in which a first conductive pattern and a plurality of pads exposed externally with respect to the package substrate are disposed, a second layer located above the first layer, and including a second conductive pattern and a floating wiring pattern having an area overlapping the plurality of pads, and a third layer located above the second layer, and including a third conductive pattern. The plurality of pads includes first group pads and second group pads, each of the first group pads and second group pads including four pads simultaneously transmitting four corresponding data signals. The floating wiring pattern includes a first floating wiring pattern having an area overlapping the first group pads, and a second floating wiring pattern having an area overlapping the second group pads. Shapes of the first floating wiring pattern and the second floating wiring pattern are different.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic diagram of a semiconductor package according to an example embodiment;

FIGS. 2 to 4 are schematic diagrams of a semiconductor package according to an example embodiment;

FIG. 5 is a schematic diagram of a package substrate according to an example embodiment;

FIGS. 6 and 7 are schematic diagrams of a portion of a package substrate according to an example embodiment;

FIGS. 8A and 8B are schematic diagrams of a portion of a package substrate according to an example embodiment;

FIG. 9 is a schematic diagram of a portion of a package substrate according to an example embodiment;

FIGS. 10 to 13 are schematic diagrams of a portion of a package substrate according to an example embodiment;

FIGS. 14A to 14C are schematic diagrams of a portion of a package substrate according to an example embodiment;

FIG. 15 is a schematic diagram of a portion of package substrates according to an example embodiment;

FIG. 16 provides cross-sectional views illustrating portions of cross-sections of package substrates according to an example embodiment;

FIG. 17 is a cross-sectional view illustrating a portion of a cross-section of a package substrate according to an example embodiment;

FIG. 18 is a cross-sectional view illustrating a portion of a cross-section of a package substrate according to an example embodiment;

FIG. 19 is a cross-sectional view illustrating a portion of a cross-section of a package substrate according to an example embodiment; and

FIG. 20 is a graph illustrating signal transmission characteristics according to an example embodiment.

### DETAILED DESCRIPTION

Hereinafter, example embodiments will be described with reference to the accompanying drawings.

The invention may be embodied in many different forms and should not be construed as limited to the example embodiments set forth herein. These example embodiments are just that-examples-and many implementations and variations are possible that do not require the details provided herein. The disclosure provides details of alternative examples, but such listing of alternatives is not exhaustive.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise.

Spatially relative terms, such as “above,” “upper,” “bottom,” “vertical” and the like, may be used herein for ease of description to describe positional relationships, such as illustrated in the figures, for example. It will be understood that the spatially relative terms encompass different orientations, in addition to the orientation depicted in the figures. Also these spatially relative terms such as “above” used herein have their ordinary broad meanings-for example element A can be above element B even if when looking down on the two elements there is no overlap between them (just as something in the sky is generally above something on the ground, even if it is not directly above).

Elements may “overlap” one another or be “overlapping”, for example when at least a portion of each element, when viewed from above or below the elements for example, overlaps at least a portion of the other element, in a plane. The elements may completely overlap one another or partially overlap one another. The elements need not physically contact or touch one another to be overlapping, as there may be space between them in another plane. For example, elements may be spaced apart vertically, but overlap one another horizontally.

It will be understood that the terms “includes” and “including” when used in this specification, specify the presence of stated features, regions, integers, steps, operations, elements and/or components, but do not preclude the presence or addition of one or more other features, regions, integers, steps, operations, elements, components, and/or groups thereof.

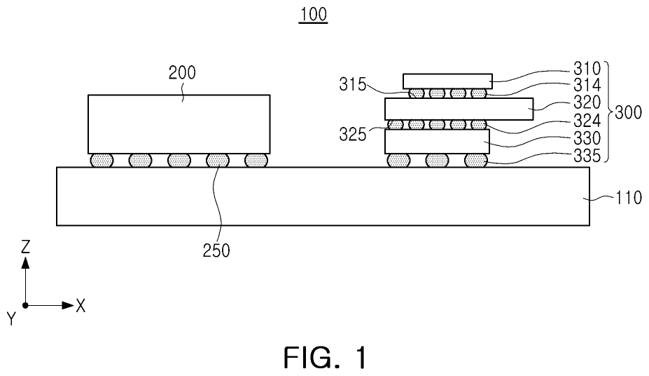

FIG. 1 is a drawing illustrating a semiconductor package according to an example embodiment. Referring to FIG. 1, a semiconductor package 100 may include a memory controller 200, a memory module 300, and a main board 110. The memory module 300 may include semiconductor chips 310, a package substrate 320, and a connector 330. The semiconductor chips 310 are mounted above the package substrate 320, and the connector 330 may connect the package substrate 320 and the main board 110.

The memory controller 200 may perform an access operation to write data to the memory module 300 or read data stored in the memory module 300. The memory controller 200 may generate a command (CMD) and an address (ADDR) for writing data to the memory module 300 or reading data stored in the memory module 300. The memory controller 200 may be at least one of a chipset for controlling the memory module 300, a system on chip (SoC) such as a mobile AP (Application Processor), a CPU (Central Processing Unit), a GPU (Graphics Processing Unit), a DPU (Data Processing Unit), and a Neural Processing Unit (NPU).

The semiconductor package 100 may include a plurality of semiconductor chips 310. The semiconductor chips 310 may receive a command (CMD) and an address (ADD) from the memory controller 200 and exchange a DQ signal (data signal) with the memory controller 200. Transmission paths for the command and address signals (CMD/ADD) and the DQ signal may be provided between the memory controller 200 and the semiconductor chips 310 through wiring (wires) provided in package substrate 320. In the example embodiment, the number of semiconductor chips 310 mounted in the semiconductor package 100 is not limited to that illustrated.

The package substrate 320 is composed of a plurality of layers (e.g. wiring layers) where adjacent such layers are separated by a dielectric material. Conductive patterns of the layers may be interconnected to provide power supply voltage(s), ground voltage(s), and signal transmission paths. The package substrate 320 may have a structure in which a plurality of layers are stacked, and may include a signal transmission pattern that transmits signals such as DQ, DQS (data strobe), and CMD/ADDR, or a conductive pattern connected to a ground voltage. The layer that is disposed at the top of the package substrate 320 in the stacking direction may include a plurality of pads 315 that are exposed externally with respect to the package substrate 320 (e.g., the pads 315 form part of the top surface of the package substrate 320), and the plurality of pads 315 may be connected to semiconductor chips 310 (directly or indirectly with other wiring, such as with solder bumps 314, redistribution layer(s), and/or interposer(s) for example). The layer that is disposed at the bottom of the package substrate 320 in the stacking direction may include a plurality of pads 325 that are exposed externally with respect to the package substrate 320 (e.g., the pads 325 form part of the bottom surface of the package substrate 320), and the plurality of pads 325 may be connected to a connector 330, for example with solder bumps 324. In example embodiments, the plurality of pads 325 and/or 315 may be part of the package substrate and 320, with a surface of the pads being exposed externally with respect to the package substrate. Pads 315 and 325 described herein may be conductive terminals and may transmit signals, ground voltages and/or supply voltages. Pads 315 and 325 may have a planar surface having horizontal dimensions greater than the horizontal dimensions of wiring (e.g., X-Y horizontal dimensions of a pad are both greater than the horizontal width of wiring of the package substrate 320 to which the pad is connected) to promote an electrical connection to a further terminal, such as a bump or solder ball, and/or an external wiring. In an example embodiment, the package substrate 320 may be LPCAMM (low-power compression attached memory modules) or CAMM.

The connector 330 may be mounted on the main board 110 to connect the semiconductor chips 310 and the package substrate 320 to the main board 110. In an example embodiment, the connector 330 may connect the package substrate 320 and the main board 110. By connecting the package substrate 320 and the main board 110 through the connector 330 instead of directly connecting them, when a defect occurs in the semiconductor chips 310 and/or the package substrate 320, only the defective semiconductor chips 310 and/or the package substrate 320 may be separated and easily replaced without replacing the entire semiconductor package 100. The connector 330 may be a ball grid array (BGA) or a pin grid array (PGA). In an example embodiment, the connector 330 may connect the package substrate 320 and the main board 110. In an example embodiment, the connector 330 may be connected to the main board 110 via solder balls 335.

In an example embodiment, the memory controller 200 may be connected to the main board 110 via solder bumps (e.g. balls, pillars, etc.) 250.

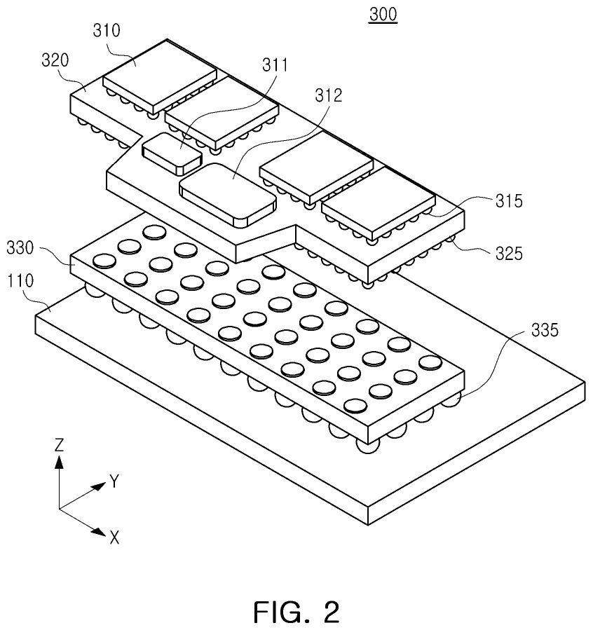

FIGS. 2 to 4 are drawings illustrating a semiconductor package according to an example embodiment.

Referring to FIG. 2, the semiconductor package may have a structure in which semiconductor chips 310-312, a package substrate 320, a connector 330, and a main board 110 are vertically stacked. Semiconductor chips 310-312 may be mounted on the upper surface of the package substrate 320. The semiconductor chips 310 mounted on the upper surface of the package substrate 320 may be at least one of a DRAM and an HBM (high bandwidth memory), and may include a Serial Presence Detector (SPD) 311 and a Power Management IC (PMIC) 312. In an example embodiment, a semiconductor package composed of a plurality of semiconductor chips may be mounted on the upper surface of the package substrate 320. The package substrate 320 includes a plurality of pads 315 exposed externally on the upper surface of the package substrate 320, and the plurality of pads 315 may be connected to semiconductor chips 310-312.

A plurality of pads 325 exposed externally may be disposed on the lower surface of the package substrate 320, and the plurality of pads 325 may be connected to a connector 330. Through the plurality of pads 315, 325 exposed externally on the upper and lower surfaces of the package substrate 320, the memory controller may transmit a command (CMD) and an address (ADD) signal to the semiconductor chips 310, or exchange a DQ signal with the semiconductor chips 310.

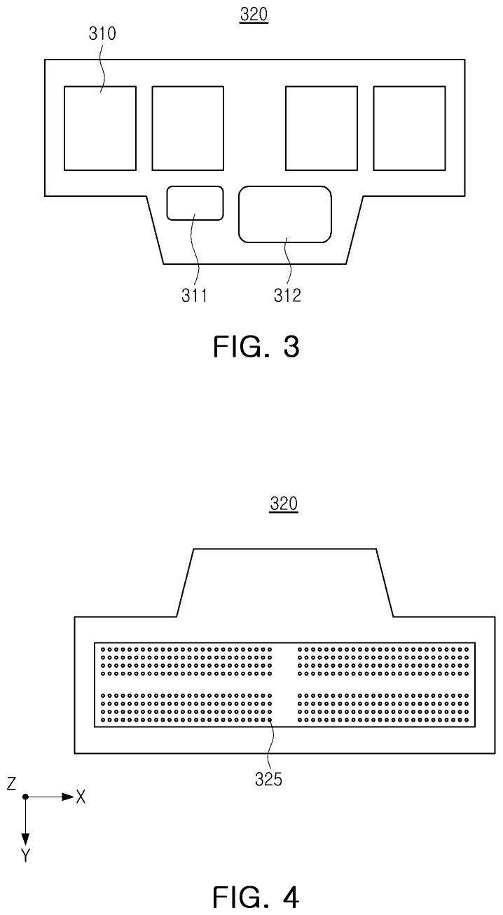

Next, referring to FIG. 3, semiconductor chips 310-312 may be mounted on the upper surface of the package substrate 320. The package substrate 320 may include a plurality of layers (e.g. wiring layers separated by dielectric material, as described herein), and the layer disposed at the topmost among the plurality of layers in the stacking direction may include a plurality of pads that are exposed externally. The plurality of pads may be connected to pads that are exposed to the outside of each of the semiconductor chips 310-312 by micro bumps and the like, and the semiconductor chips 310-312 may be mounted on the package substrate 320 by the plurality of pads. In an example embodiment, the semiconductor chips 310 mounted above the package substrate 320 may be a single semiconductor chip or may be a semiconductor package including a plurality of semiconductor chips.

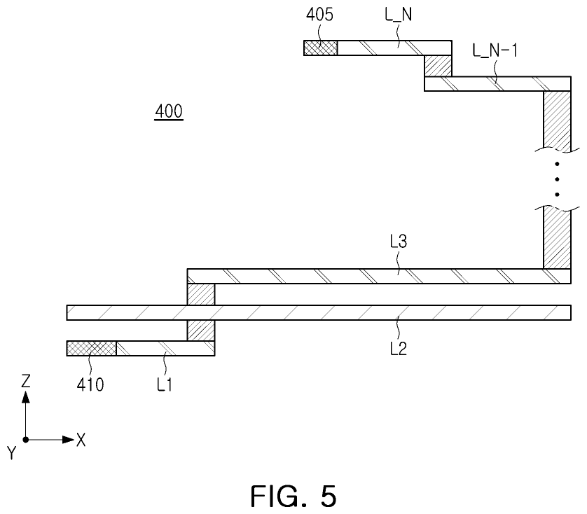

Referring to FIG. 4, the layer disposed bottommost among the plurality of layers included in the package substrate 320 in the stacking direction may include a plurality of pads 325 that are exposed externally. The plurality of pads 325 may be connected to a connector. Through the plurality of pads 325, the memory controller may transmit command (CMD) and address (ADD) signals to the semiconductor chips 310, or exchange DQ signals with the semiconductor chips.

In an example embodiment, at least one layer may be placed above the layer disposed at the lowest position among the plurality of layers including the plurality of pads 325 exposed externally with respect to the package substrate. The layer disposed at the lowest position among the plurality of layers may be a first layer, and the layer disposed above the first layer may be a second layer. The second layer may include a second conductive pattern. The second conductive pattern may be connected to a ground voltage, thereby attenuating noise generated in signal wiring patterns included in other adjacent layers from affecting signals transmitted through the plurality of pads.

In example embodiments, the second wiring layer is the layer directly above the first wiring layer.

As communication devices or computers become faster, crosstalk noise may occur between adjacent signal wiring patterns, which may deteriorate signal characteristics such as signal quality and speed. To minimize the degradation of signal characteristics when transmitting signals at high speed, the second layer may include a floating wiring pattern having an area overlapping a plurality of pads. The floating wiring pattern may form capacitance with a plurality of pads, thereby compensating for inductance in a wiring pattern where the influence of inductance is dominant, thereby reducing crosstalk noise.

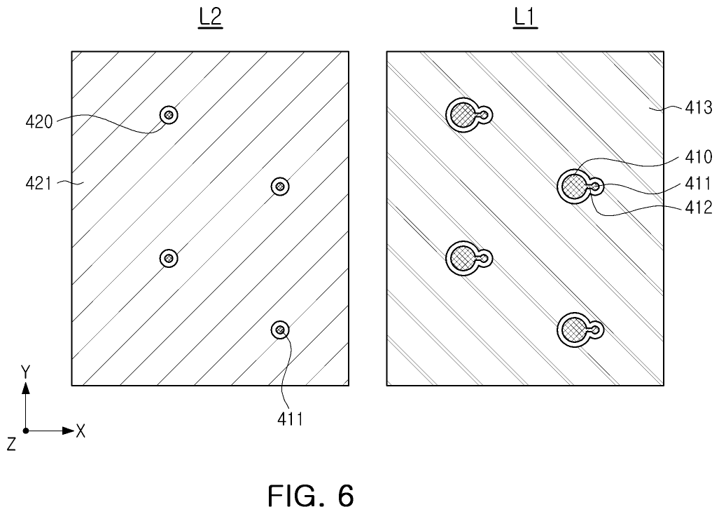

FIG. 5 is a cross-sectional view illustrating a cross-section of a package substrate 400 according to an example embodiment. Package substrate 400 is an example of package substrate 320.

The package substrate 400 includes a plurality of layers (e.g., wiring layers) L1, L2, . . . . LN-1, L_N (which may be generically referenced as layer or layers L), separated by a dielectric material (not shown). Some or all of the layers L, and may include a signal transmission pattern that transmits signals such as DQ, DQS, CMD/ADDR, or a conductive pattern connected to a ground voltage. Referring to FIG. 5, the first layer L1 positioned at the bottom of the package substrate 400 in the stacking direction may include a plurality of pads 410 that are exposed externally. Through the plurality of pads 410, the memory controller may transmit command and address signals to semiconductor chips or exchange DQ signals with the semiconductor chips. Non-limiting examples of suitable dielectric materials may include for example, at least one compound selected from silicon dioxide (SiO₂), silicon nitride (Si₃N₄), aluminum oxide (Al₂O₃), tantalum oxide (Ta₂O₅), barium titanate (BaTiO₃), hafnium oxide (HfO₂), and zirconium oxide (ZrO₂), and various polymer films such as polyimide and parylene.

The second layer L2 is located above the first layer L1 and may include a second conductive pattern. The second conductive pattern may be connected to a ground voltage. The second conductive pattern may weaken the influence of noise generated in the signal wiring pattern included in the other layers adjacent to the first layer L1 on the signal transmitted to the first layer L1. For example, the second layer L2 may reduce the influence of electromagnetic waves generated in the signal wiring pattern included in the third layer L3 on the signal transmitted to the first layer L1.

The layer (L_N) stacked on the topmost side of the package substrate 400 may include a plurality of pads 405 that are exposed externally. Through the plurality of pads 405, the memory controller may transmit command and address signals to the semiconductor chips or exchange DQ signals with the semiconductor chips. A plurality of layers (e.g. L_N-1) may exist between the layer (L_N) stacked on the topmost side and the first layer L1. In an example embodiment, the package substrate 400 may include ten layers, but the number of layers included in the package substrate 400 is not limited thereto.

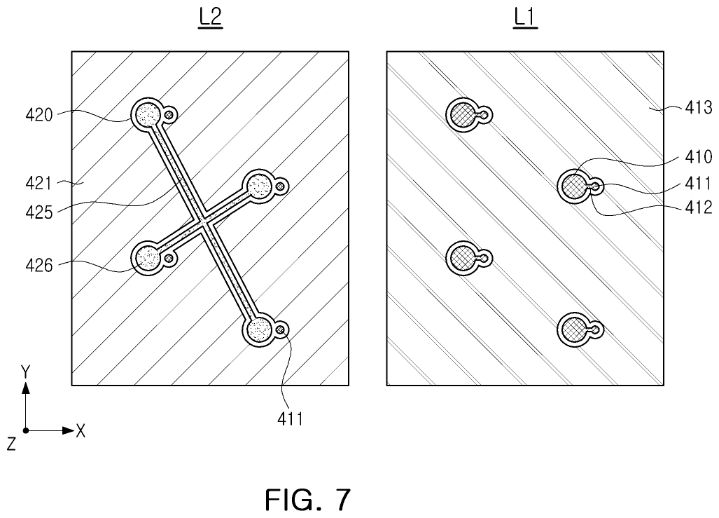

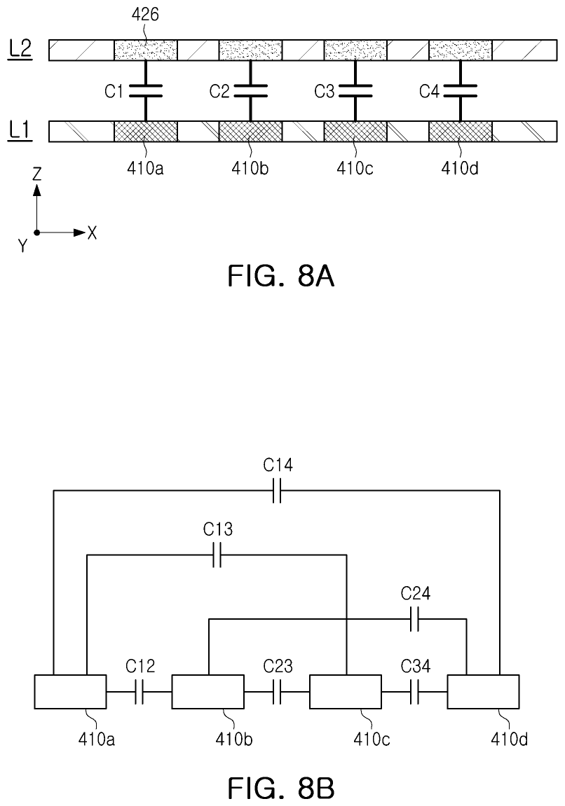

FIGS. 6 and 7 are cross-sectional views illustrating a portion of a package substrate according to an example embodiment.

Referring to FIG. 6, the first layer L1 may include a first conductive pattern 412, a plurality of pads 410 exposed externally, and vias 411. The first conductive pattern 412, the plurality of pads 410, and vias 411 may be disposed on a ground plane 413. The gap between the ground plane 413 and the first conductive pattern 412, the plurality of pads 410, and vias 411 may be filled with a dielectric material. The plurality of pads 410 may transmit signals between semiconductor chips and a memory controller. The vias 411 may extend from the first layer L1 to the third layer L3 in the first direction (Z-axis direction). A signal transmitted to the plurality of pads 410 may be transmitted to the semiconductor chips through the vias 411, or a signal transmitted from the semiconductor chips may be transmitted to the plurality of pads 410 through the vias 411. In the first layer L1, the first conductive pattern 412 may connect a plurality of pads 410 and vias 411.

The second layer L2 may be placed above the first layer L1 and below the third layer L3. The second layer L2 may include a second conductive pattern 421 connected to a ground voltage. In some examples, the second layer L2 may be a ground plane and substantially form of a metal sheet that, with respect to a top down view, has an area substantially the same as that of the package substrate 400 (e.g., the dimensions in the X and Y directions of the metal sheet of the second layer L2 may be the same as those of the package substrate 400). This metal sheet may correspond to the second conductive pattern 421. The second conductive pattern 421 may include a plurality of holes 420. The gap between the second conductive pattern 421 and the plurality of holes 420 may be filled with a dielectric material. The plurality of holes 420 may provide a path through which the vias 411 may pass.

As communication devices or computers become faster, crosstalk noise may occur between adjacent signal wiring patterns, and the characteristics of the signal, such as the quality and speed of the signal, may deteriorate. To process signals accurately and quickly, the crosstalk noise may be reduced by matching the impedance values. In a package substrate where the influence of inductance is dominant, crosstalk noise may be reduced by forming capacitance or greatly optimizing the value of capacitance.

In an example embodiment, the package substrate may include a plurality of layers. The plurality of layers may include a first layer L1 and a second layer L2. The first layer L1 may include a plurality of pads 410 exposed externally. The second layer L2 may include a second conductive pattern 421 connected to a ground voltage, and a floating wiring pattern having an area overlapping the plurality of pads 410. By forming the floating wiring pattern in the second layer L2, capacitance may be formed between the floating wiring pattern and the plurality of pads 410. In a package substrate where the influence of inductance is dominant, capacitance may be intentionally generated by adding the floating wiring pattern, and crosstalk noise due to inductance may be improved.

Referring to FIG. 7, the second layer L2 may be positioned above the first layer L1 and may include a second conductive pattern 421 and a floating wiring pattern 425. The second conductive pattern 421 may be connected to a ground voltage and may include a plurality of holes 420 that provide a path through which vias 411 may pass. The floating wiring pattern 425 may be separated from the vias 411.

The floating wiring pattern 425 may include a terminal portion 426 having an area overlapping a pad of the plurality of pads 410. The terminal portion 426 of the floating wiring pattern 425 may have an area overlapping two or more pads among the plurality of pads 410 disposed in the first layer L1, and the number of pads overlapping the terminal portion 326 of the floating wiring pattern 425 may vary depending on some example embodiments. By including the floating wiring pattern 425 having an area overlapping the plurality of pads 410 in the second layer L2, capacitance may be generated between the plurality of pads 410 and the terminal portion 426 of the floating wiring pattern 425.

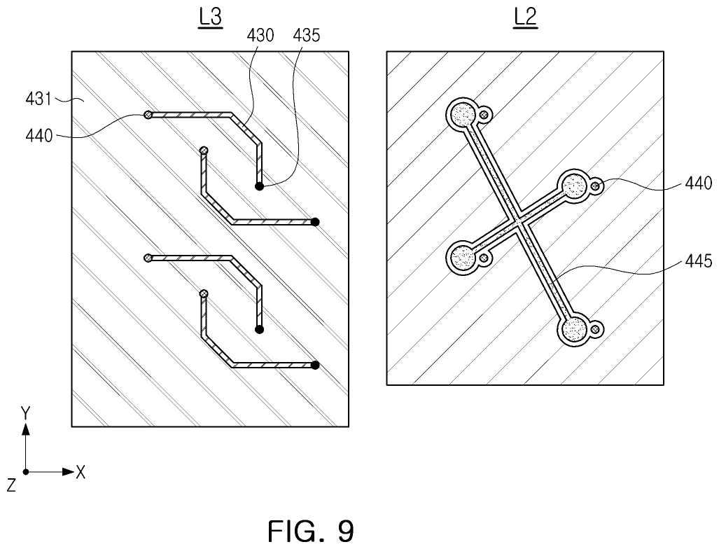

In an example embodiment, the floating wiring pattern 425 may have an area overlapping four pads among the plurality of pads 410. Capacitance may be generated between the terminal portion 426 of the floating wiring pattern 425 and the four pads. According to an example embodiment, because capacitance is generated between respective pads, the total capacitance reflected in the wiring pattern connected to the plurality of pads 410 may also include the capacitance between the pads. The capacitances generated by the plurality of pads 410 and the floating wiring pattern 425 will be described with reference to FIGS. 8A and 8B. By intentionally adding capacitance to the wiring pattern where the influence of inductance is dominant, crosstalk noise may be reduced.

FIGS. 8A and 8B are cross-sectional views illustrating a portion of a cross-section of a package substrate according to an example embodiment.

In an example embodiment, the signal wiring pattern of the package substrate may be dominated by the influence of inductance. When the influence of inductance is dominant, crosstalk noise is generated by the inductance, which may deteriorate the characteristics of the signal, such as the quality and speed of the signal. To minimize the influence of crosstalk noise, the second layer L2 may include a floating wiring pattern 425. Capacitance may be formed between the plurality of pads 410a-410d and the floating wiring pattern 425. By forming capacitance in the package substrate where the influence of inductance is dominant, crosstalk noise caused by inductance may be improved, thereby improving the characteristics of signals transmitted from the package substrate.

Referring to FIG. 8A, capacitance may be formed between each terminal portion 426 of the floating wiring pattern 425 included in the second layer L2 and a corresponding pad of the plurality of pads 410a-410d included in the first layer L1. The plurality of pads may include a first pad 410a, a second pad 410b, a third pad 410c, and a fourth pad 410d. A first capacitance C1, a second capacitance C2, a third capacitance C3, and a fourth capacitance C4 may be generated between each terminal portion 426 of the floating wiring pattern 425 and a corresponding pad, e.g., the first pad 410a, the second pad 410b, the third pad 410c, and the fourth pad 410d, respectively.

Referring to FIG. 8B, capacitance may also be formed between adjacent pads 410a-410d. Capacitance C12 may be formed between the first pad 410a and the second pad 410b, capacitance C23 may be formed between the second pad 410b and the third pad 410c, capacitance C34 may be formed between the third pad 410c and the fourth pad 410d, capacitance C13 may be formed between the first pad 410a and the third pad 410c, capacitance C24 may be formed between the second pad 410b and the fourth pad 410d, and capacitance C14 may be formed between the first pad 410a and the fourth pad 410d. By including a floating wiring pattern 425 in the second layer L2, a total of 10 capacitances C1, C2, C3, C4, C12, C13, C14, C23, C24 and C34 may be formed between the floating wiring pattern 425 and the plurality of pads 410a-410d, and between respective pads.

By including a floating wiring pattern 425 having an overlapping area with the plurality of pads 410a-410d in the second layer L2, capacitance may be formed between the end of the floating wiring pattern 425 and the plurality of pads 410a-410d, and between respective pads 410a-410d. By forming capacitance in a signal wiring pattern where the influence of inductance is dominant, crosstalk noise due to inductance may be reduced, and a package substrate and a semiconductor package including the same may be provided which may improve signal characteristics.

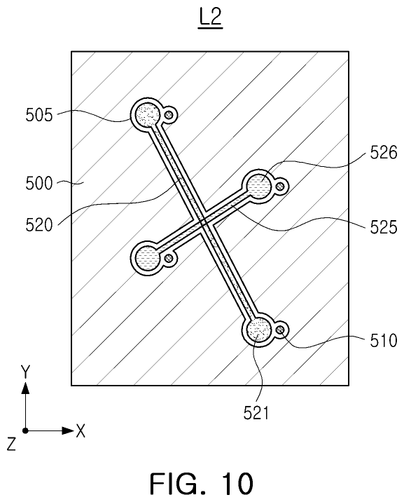

FIG. 9 is a cross-sectional view illustrating a portion of a package substrate according to an example embodiment.

In an example embodiment, the package substrate may include a plurality of layers. The plurality of layers may include a first layer L1, a second layer L2, and a third layer L3. The first layer L1 may be a layer including a plurality of pads exposed externally. The second layer L2 may be stacked above the first layer L1, and the third layer L3 may be stacked above the second layer L2. In example embodiments, at least one layer may be stacked above the third layer L3.

Referring to FIG. 9, the third layer L3 may include a third conductive pattern 430, first vias 440, and second vias 435. The first vias 440 may extend from the first layer L1 to the third layer L3 in the first direction. The third conductive pattern 430, the first vias 440, and the second vias 435 may be disposed on a dielectric plane 431. The dielectric plane 431 may be adjacent to the third conductive pattern 430. The third conductive pattern 430 may connect between the first vias 440 and the second vias 435. The third conductive pattern 430 may be a signal wiring pattern that transmits a data signal. The signals transmitted to the first vias 440 may be transmitted to the second vias 435 through the third conductive pattern 430, or the signals transmitted to the second vias 435 may be transmitted to the first vias 440 through the third conductive pattern 430. The second vias 435 may extend from the third layer L3 in the first direction to at least one layer stacked above the third layer L3.

In an example embodiment, the floating wiring pattern 445 included in the second layer L2 may not completely overlap with the third conductive pattern 430 included in the third layer L3. Some areas of the floating wiring pattern 445 and the third conductive pattern 430 may overlap, but the path of the floating wiring pattern 445 may not follow the path of the third conductive pattern 430. In an example embodiment, the third conductive pattern 430 is not a straight line, and the floating wiring pattern 445 may be a straight line. Because the path of the floating wiring pattern 445 does not completely overlap the path of the third conductive pattern 430, the characteristics of the signal transmitted from the third conductive pattern 430 may be prevented from being degraded by the floating wiring pattern 445.

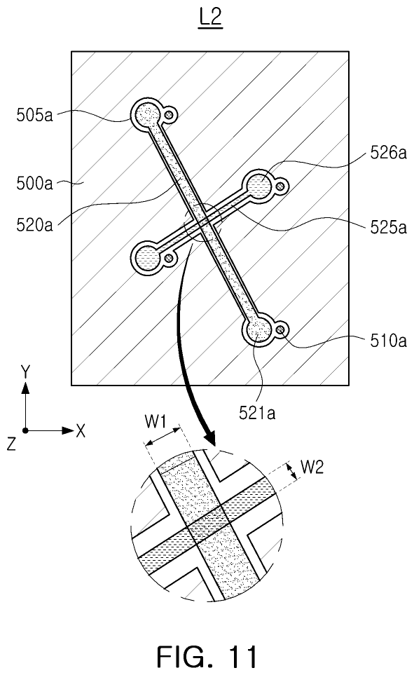

FIGS. 10 to 13 are cross-sectional views illustrating a portion of a cross-section of a package substrate according to an example embodiment.

A plurality of layers included in the package substrate may include a first layer L1 on which a plurality of pads exposed externally are disposed, and a second layer L2 positioned above the first layer L1. The second layer L2 may include a second conductive pattern 500, vias 510, and a floating wiring pattern 520, 525 having an area overlapping a plurality of pads. The second conductive pattern 500 may include a plurality of holes 505 that provide a path through which vias 510 may pass.

The floating wiring pattern may include a first floating wiring pattern 520 and a second floating wiring pattern 525. The first floating wiring pattern 520 may include a first terminal portion 521 having an area overlapping a pad of a plurality of pads, and the second floating wiring pattern 525 may include a second terminal portion 526 having an area overlapping a plurality of pads. The first floating wiring pattern 520 and the second floating wiring pattern 525 may be located on the same plane. In an example embodiment, some areas of the first floating wiring pattern 520 and the second floating wiring pattern 525 may overlap each other.

Referring to FIG. 10, the first length of the first floating wiring pattern 520 may be longer than the second length of the second floating wiring pattern 525. Even if the lengths of the first floating wiring pattern 520 and the second floating wiring pattern 525 are different, capacitance may be formed between the terminal portion 521 of the first floating wiring pattern 520 and the plurality of pads, and between the terminal portion 521 of the second floating wiring pattern 525 and the plurality of pads. In a package substrate where the influence of inductance is dominant, crosstalk noise due to inductance may be reduced by arbitrarily generating capacitance.

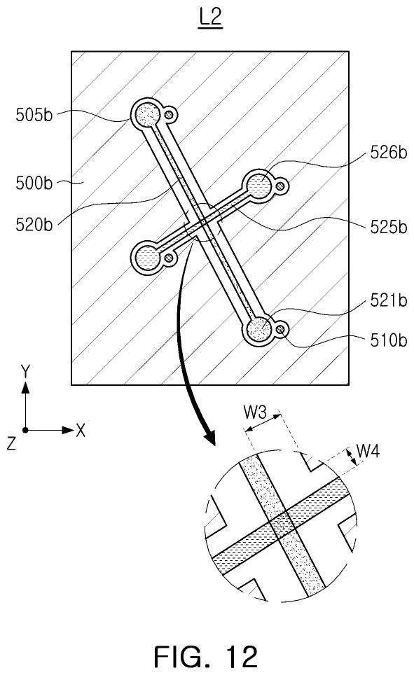

Referring to FIG. 11, the package substrate may include a plurality of layers, each layer of the plurality of layers including a respective conductive pattern. Each layer may also include a base layer, which may be an insulating layer having openings (e.g., trenches, holes, etc. extending through the insulating layer) formed therein. The conductive patterns may be formed in these openings (e.g., trenches, holes) of the base layer. The plurality of layers may include a first layer L1 including a plurality of pads exposed externally with respect to the package substrate, and a second layer L2 disposed above the first layer L1. The second layer L2 may include a second conductive pattern 500a, vias 510a, and floating wiring patterns 520a and 525a having an area overlapping the plurality of pads. The second conductive pattern 500a may include a plurality of holes 505a.

The floating wiring pattern included in the second layer may include a first floating wiring pattern 520a and a second floating wiring pattern 525a. The first floating wiring pattern 520a may include a first terminal portion 521a having an area overlapping a plurality of pads, and the second floating wiring pattern 525a may include a second terminal portion 526a having an area overlapping a plurality of pads.

In an example embodiment, the first width W1 of the first floating wiring pattern 520a may be larger than the second width W2 of the second floating wiring pattern 525a. Even if the first width of the first floating wiring pattern 520a and the second width of the second floating wiring pattern 525a are different from one another, capacitance may be formed between the first terminal portion 521a and the plurality of pads, and between the second terminal portion 526a and the plurality of pads. In a package substrate where the influence of inductance is dominant, crosstalk noise due to inductance may be reduced by arbitrarily generating the capacitance.

It should be understood that the width of a wiring is in a direction perpendicular to the extending direction of the wiring, where the extending direction is the path of the wiring (e.g., corresponding to the current path provided by the wiring). As the entire path of a wiring may not be linear, it should be appreciated that the extending direction of a wiring may change along the length of the wiring (and likewise, the width direction changes). For a linear segment of wiring, the length of the wiring segment in the extending direction is greater than its width (perpendicular to that extending direction).

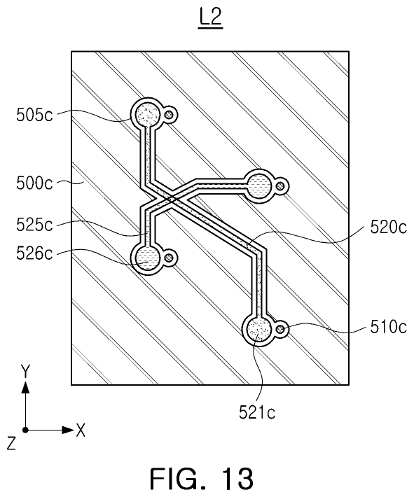

Referring to FIG. 12, the plurality of layers included in the package substrate may include a first layer L1 including a plurality of pads exposed externally, and a second layer L2 disposed above the first layer L1. The second layer L2 may include a second conductive pattern 500b, vias 510b, and first and second floating wiring patterns 520b and 525b having an area overlapping the plurality of pads. The second conductive pattern 500b may include a plurality of holes 505b.

The floating wiring pattern included in the second layer L2 may include a first floating wiring pattern 520b and a second floating wiring pattern 525b. The first floating wiring pattern 520b may include a first terminal portion 521b having an area overlapping the plurality of pads, and the second floating wiring pattern 525b may include a second terminal portion 526b having an area overlapping the plurality of pads.

In an example embodiment, the first gap W3 between the first floating wiring pattern 520b and the second conductive pattern 500b may be larger than the second gap W4 between the second floating wiring pattern 525b and the second conductive pattern 500b. Even if the first gap W3 between the first floating wiring pattern 520b and the second conductive pattern 500b and the second gap W4 between the second floating wiring pattern 525b and the second conductive pattern 500b are different, capacitance may be formed between the first terminal portion 521b and the plurality of pads, and between the second terminal portion 526b and the plurality of pads. In a package substrate where the influence of inductance is dominant, crosstalk noise due to inductance may be reduced by arbitrarily generating capacitance. A “gap” may still exist between two elements even when the gap is filled.

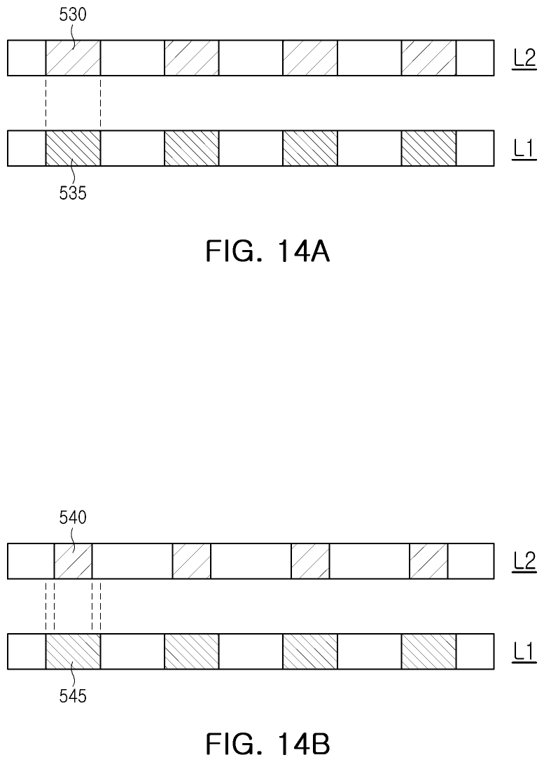

Referring to FIG. 13, the plurality of layers included in the package substrate may include a first layer L1 including a plurality of pads exposed externally, and a second layer L2 disposed above the first layer L1. The second layer L2 may include a second conductive pattern 500c, vias 510c, and first and second floating wiring patterns 520c and 525c having an area overlapping the plurality of pads. The second conductive pattern 500b may include a plurality of holes 505c.

The floating wiring pattern included in the second layer L2 may include a first floating wiring pattern 520c and a second floating wiring pattern 525c. The first floating wiring pattern 520c may include a first terminal portion 521c having an area overlapping the plurality of pads, and the second floating wiring pattern 525c may include a second terminal portion 526c having an area overlapping the plurality of pads.

In an example embodiment, at least one of the first floating wiring pattern 520c and the second floating wiring pattern 525c may not be a straight line. However, the shape of the floating wiring patterns 520c and 525c is not limited to the shape illustrated in FIG. 13. Even if the first floating wiring pattern 520c and the second floating wiring pattern 525c are not a straight line, capacitance may be formed between the first terminal portion 521c and the plurality of pads, and between the second terminal portion 526c and the plurality of pads. In a package substrate where the influence of inductance is dominant, crosstalk noise due to inductance may be reduced by arbitrarily generating capacitance.

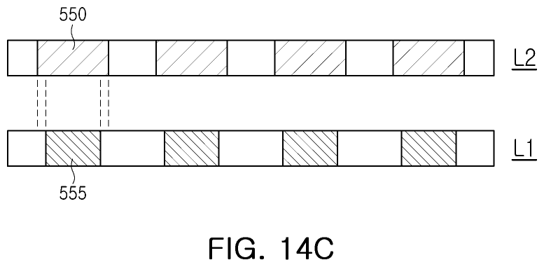

FIGS. 14A to 14C are cross-sectional views illustrating a portion of a package substrate according to an example embodiment.

The package substrate may include a plurality of layers, each layer of the plurality of layers having a respective conductive pattern. Each layer may also include a base layer. The plurality of layers may include a first layer L1 and a second layer L2 disposed above the first layer L1. The first layer L1 may include a plurality of pads 535 exposed externally, and the second layer L2 may include a floating wiring pattern having a terminal portion 530 having an area overlapping the plurality of pads 535.

Referring to FIG. 14A, the terminal portion 530 of the floating wiring pattern may be an area having the same size as the plurality of pads 535. Capacitance may be formed between the terminal portion 530 of the floating wiring pattern and the plurality of pads 535. By arbitrarily forming capacitance between the terminal 530 and the plurality of pads 535, crosstalk noise due to inductance may be reduced in a wiring pattern where the influence of inductance is dominant. By controlling the size of the terminal 530 included in the floating wiring pattern, the magnitude of the capacitance formed between the terminal 530 and the plurality of pads 535 may be controlled, so that an optimal capacitance may be implemented to minimize crosstalk noise due to inductance.

Referring to FIG. 14B, the terminal 540 of the floating wiring pattern may be an area having a smaller size than an area of the plurality of pads 545. Referring to FIGS. 14A and 14B together, the magnitude of the capacitance formed between the terminal portion 540 of the floating wiring pattern and the plurality of pads 535 illustrated in FIG. 14B may be smaller than the magnitude of the capacitance formed between the terminal portion 530 of the floating wiring pattern and the plurality of pads 535 illustrated in FIG. 14A. In a wiring pattern where the influence of inductance is dominant, crosstalk noise due to inductance may be reduced by arbitrarily generating capacitance. By controlling the size of the terminal portion 540 of the floating wiring pattern having an area overlapping the plurality of pads 545, the magnitude of the capacitance formed between the plurality of pads 545 and the terminal portion 540 may be controlled. Therefore, an optimal capacitance may be implemented to minimize crosstalk noise due to inductance.

Referring to FIG. 14c, the terminal portion 550 of the floating wiring pattern may be an area having a larger size than the plurality of pads 555. Referring to FIGS. 14a and 14c together, the magnitude of the capacitance formed between the terminal portion 550 of the floating wiring pattern and the plurality of pads 555 illustrated in FIG. 14c may be larger than the magnitude of the capacitance formed between the terminal portion 530 of the floating wiring pattern and the plurality of pads 535 illustrated in FIG. 14a. In a wiring pattern where the influence of inductance is dominant, crosstalk noise due to inductance may be reduced by arbitrarily generating capacitance. By controlling the size of the terminal portion 550 of the floating wiring pattern having an area overlapping the plurality of pads 555, the magnitude of the capacitance formed between the plurality of pads 555 and the terminal portion 550 may be controlled. Therefore, the optimal capacitance may be implemented to minimize crosstalk noise due to inductance.

By varying the shape of the terminal portion included in the floating wiring pattern, the magnitude of the capacitance formed between the plurality of pads and the terminal may be controlled. In an example embodiment, referring to FIGS. 10 to 13 together, the shape of the terminal of the floating wiring pattern may be circular. However, as illustrated in FIGS. 10 to 13, the shape of the terminal is not limited to a circular shape, and may be other shapes such as a square, a triangle, an oval, and the like. By varying the shape of the terminal included in the floating wiring pattern, the magnitude of the capacitance formed between the plurality of pads and the terminal may be controlled. Therefore, the optimal capacitance may be implemented to minimize crosstalk noise due to inductance.

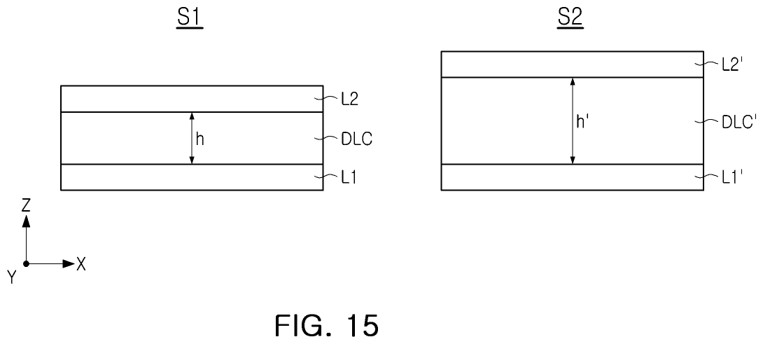

FIG. 15 is a cross-sectional view illustrating a portion of a package substrate according to an example embodiment.

The package substrate may include a plurality of layers, each layer of the plurality of layers having a respective conductive pattern. Each layer may also include a base layer. A dielectric layer formed of a dielectric material is disposed between respective layers, and in example embodiments, each layer may include a base layer, which may also be formed of a dielectric material.

The magnitude of the capacitance formed between the floating wiring pattern and the plurality of pads may vary depending on the thickness or permittivity of the dielectric layer disposed between the layer where the floating wiring pattern is formed and the layer where the plurality of pads are formed. By varying the thickness or permittivity of the dielectric material, the magnitude of the capacitance may be varied, and the optimal capacitance for significantly reducing crosstalk noise may be implemented.

In an example embodiment, to implement the optimal capacitance for significantly reducing crosstalk noise, the thickness of the dielectric layer disposed between the layers may vary. The material filled between the first layer L1 and the second layer L2 included in the first package substrate S1 may be the first dielectric (DLC), and the material filled between the first layer L1′ and the second layer L2′ included in the second package substrate S2 may be the second dielectric (DLC′).

Referring to FIG. 15, the thickness h of the first dielectric (DLC) and the thickness h′ of the second dielectric (DLC′) may be different. Thickness may refer to the thickness or height measured in a direction perpendicular to a top surface of the package substrate. In an example embodiment, the thickness h′ of the second dielectric (DLC′) may be greater than the thickness h of the first dielectric (DLC). Therefore, the magnitude of the capacitance generated between the first layer L1 and the second layer L2 included in the first package substrate S1 may be greater than the magnitude of the capacitance generated between the first layer L1′ and the second layer L2′ included in the second package substrate S2. In a package substrate where the influence of inductance is dominant, crosstalk noise due to inductance may be reduced by arbitrarily generating capacitance. Because the magnitude of the capacitance generated may be controlled by controlling the thicknesses h and h′ of the dielectric materials DLC and DLC′ respectively, filled between the first layers L1 and L1′ and the second layers L2 and L2′, the optimal capacitance for significantly reducing crosstalk noise due to the influence of inductance may be implemented.

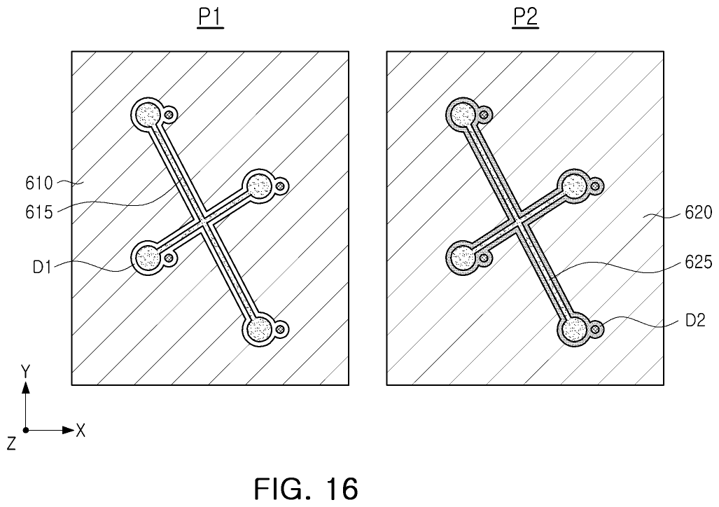

FIG. 16 is a cross-sectional view illustrating a portion of a cross-section of package substrates according to an example embodiment.

A semiconductor package may include semiconductor chips, a package substrate, a connector, a main board, and the like. The package substrate may include a plurality of layers, and the plurality of layers may include a first layer and a second layer positioned above the first layer. The first layer may include a plurality of pads exposed externally with respect to the package substrate, and the second layer may include a floating wiring pattern having an area overlapping the second conductive pattern and the plurality of pads.

According to an example embodiment, by making the dielectric constant of the dielectric material filled between the floating wiring pattern and the second conductive pattern different, the magnitude of the capacitance generated between the floating wiring pattern and the plurality of pads may be made different. The second layer of the first semiconductor package PI may include the first floating wiring pattern 615, and the second layer of the second semiconductor package P2 may include the second floating wiring pattern 625.

Referring to FIG. 16, the dielectric material filled between the first floating wiring pattern 615 and the second conductive pattern 610 of the first semiconductor package P1 may be the first dielectric D1, and the dielectric material filled between the second floating wiring pattern 625 and the second conductive pattern 620 of the second semiconductor package P2 may be the second dielectric D2. In an example embodiment, the first dielectric D1 and the second dielectric D2 may have different dielectric constants. Because the dielectric constants of the first dielectric D1 and the second dielectric D2 are different, the magnitude of the capacitance generated between the first floating wiring pattern 615 and the plurality of pads may be different from the magnitude of the capacitance generated between the second floating wiring pattern 625 and the plurality of pads.

For example, if the second dielectric D2 has a higher dielectric constant than the first dielectric D1, the magnitude of the capacitance generated between the second floating wiring pattern 625 included in the second semiconductor package (P2 and the plurality of pads may be greater than the magnitude of the capacitance generated between the first floating wiring pattern 615 included in the first semiconductor package (P1 and the plurality of pads. In a package substrate where the influence of inductance is dominant, crosstalk noise due to inductance may be reduced by arbitrarily generating capacitance. By varying the permittivity of the dielectric materials D1 and D2 filled between the floating wiring patterns 615 and 625 and the second conductive pattern 610, 620, the size of the generated capacitance may be controlled, so that the optimal capacitance for significantly reducing crosstalk noise may be implemented.

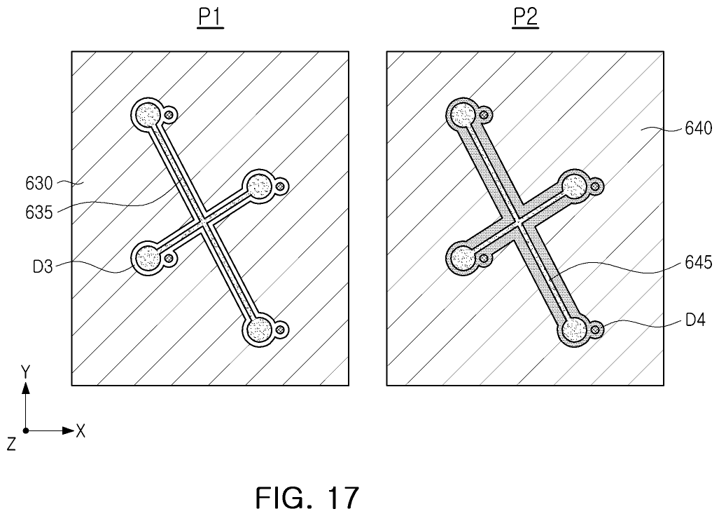

FIG. 17 is a cross-sectional view illustrating a portion of a package substrate according to an example embodiment.

In an example embodiment, the second layer of the first semiconductor package P1 may include a first floating wiring pattern 635, and the second layer of the second semiconductor package P2 may include a second floating wiring pattern 645. The dielectric material filled between the first floating wiring pattern 635 and the second conductive pattern 630 of the first semiconductor package P1 may be a third dielectric D3, and the dielectric material filled between the second floating wiring pattern 645 and the second conductive pattern 640 of the second semiconductor package P2 may be a fourth dielectric D4. Depending on some example embodiments, a third gap between the first floating wiring pattern 635 and the second conductive pattern 630 of the first semiconductor package P1 may be different from a fourth gap between the second floating wiring pattern 645 and the second conductive pattern 640 of the second semiconductor package P2.

Referring to FIG. 17, the third gap between the first floating wiring pattern 635 and the second conductive pattern 630 of the first semiconductor package P1 may be smaller than the fourth gap between the second floating wiring pattern 645 and the second conductive pattern 640 of the second semiconductor package P2. Even if the third gap between the first floating wiring pattern 635 and the second conductive pattern 630 of the first semiconductor package P1 and the fourth gap between the second floating wiring pattern 645 and the second conductive pattern 640 of the second semiconductor package P2 are different, capacitance may be formed between the first floating wiring pattern 635 and the plurality of pads, and between the second floating wiring pattern 645 and the plurality of pads. In a package substrate where the influence of inductance is dominant, crosstalk noise due to inductance may be reduced by arbitrarily generating capacitance.

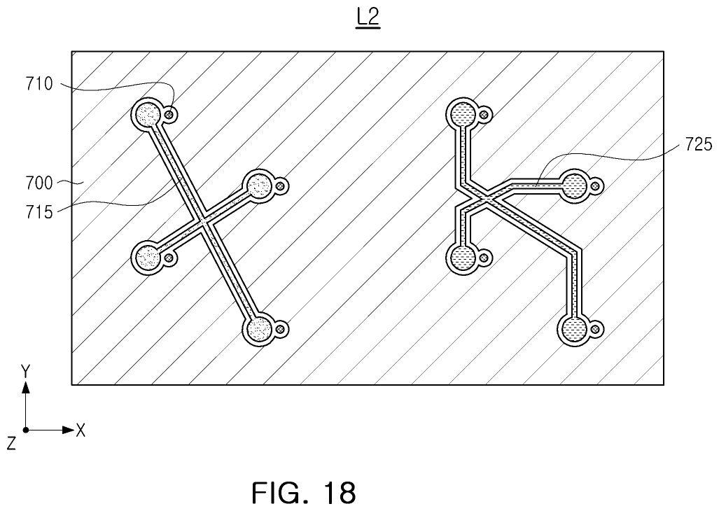

FIG. 18 is a cross-sectional view illustrating a portion of the package substrate according to an example embodiment.

Data signals transmitted through the package substrate may be transmitted as a single group unit. In an example embodiment, the data signal transmitted through the package substrate may be a DQ signal. The DQ signals transmitted through the package substrate may be transmitted in units of one data signal group. According to an example embodiment, one data signal group may include four DQ signals, eight DQ signals, or sixteen DQ signals.

One data signal group may be synchronized according to one DQS signal. The DQS signal may be a clock signal transmitted together with the DQ signal to accurately control the timing of one data signal group in the semiconductor package. By synchronizing one data signal group through one DQS signal, the delay of the signal transmitted from the package substrate may be reduced, and the characteristics of the signal, such as the quality of the signal and the transmission speed of the signal, may be improved.

In an example embodiment, the DQ signals transmitted through the package substrate may be transmitted in units of one data signal group. One data signal group may include four DQ signals and may be synchronized by one DQS signal.

The package substrate may have a structure in which a plurality of layers, each including a conductive pattern, are stacked. The plurality of layers may include a first layer including a plurality of pads exposed externally, and a second layer disposed above the first layer. The second layer may include a second conductive pattern 700 connected to a ground voltage, and a floating wiring pattern having an area overlapping the plurality of pads. The plurality of pads may include group pads that simultaneously transmit the respective data signal groups, and the floating wiring pattern may include floating wiring patterns 715, 725 having an area overlapping the respective group pads.

A floating wiring pattern included in a second layer L2 may include a first floating wiring pattern 715 and a second floating wiring pattern 725. The first floating wiring pattern 715 may have an overlapping area with the first group pads, and the second floating wiring pattern 725 may have an overlapping area with the second group pads. The first group pads may transmit a first data signal group, and the second group pads may transmit a second data signal group. The first data signal group may be synchronized by the first DQS signal, and the second data signal group may be synchronized by the second DQS signal. The first data signal group may include four DQ signals, DQ0, DQ1, DQ2, and DQ3, and the second data signal group may include four DQ signals, DQ4, DQ5, DQ6, and DQ7.

Referring to FIG. 18, the shapes of the first floating wiring pattern 715 and the second floating wiring pattern 725 may be different from each other. The first floating wiring pattern 715 and the second floating wiring pattern 725 may be different in at least one of the length, width, and shape. Even if the first floating wiring pattern 715 and the second floating wiring pattern 725 are different, capacitance may be formed between the first floating wiring pattern 715 and the first group pads and between the second floating wiring pattern 725 and the second group pads. In a package substrate where the influence of inductance is dominant, crosstalk noise due to inductance may be reduced by arbitrarily generating capacitance.

The first floating wiring pattern 715 may include a first terminal portion having an overlapping area with the first group pads, and the second floating wiring pattern 725 may include a second terminal portion having an overlapping area with the second group pads. The first terminal portion and the second terminal portion may have different sizes and shapes. By making the sizes and shapes of the first terminal portion and the second terminal portion different, the sizes of the capacitances formed between the first terminal portion and the first group pads and between the second terminal portion and the second group pads may be different. By making the sizes and shapes of the terminal portions included in the floating wiring pattern having an overlapping area with respective group pads different, the magnitude of the capacitance generated may be adjusted, so that an optimal capacitance for significantly reducing crosstalk noise may be implemented.

The second layer L2 may include a floating wiring pattern having an overlapping area with respective group pads, for respective group pads that simultaneously transmit one data signal group. Respective group pads have an area overlapping the same floating wiring pattern, and respective group pads and the floating wiring pattern may form capacitance of the same or substantially the same magnitude. In a package substrate where the influence of inductance is dominant, crosstalk noise due to inductance may be reduced by arbitrarily generating capacitance. By adjusting the size of capacitance for respective data signal groups, an optimal capacitance for significantly reducing crosstalk noise may be implemented.

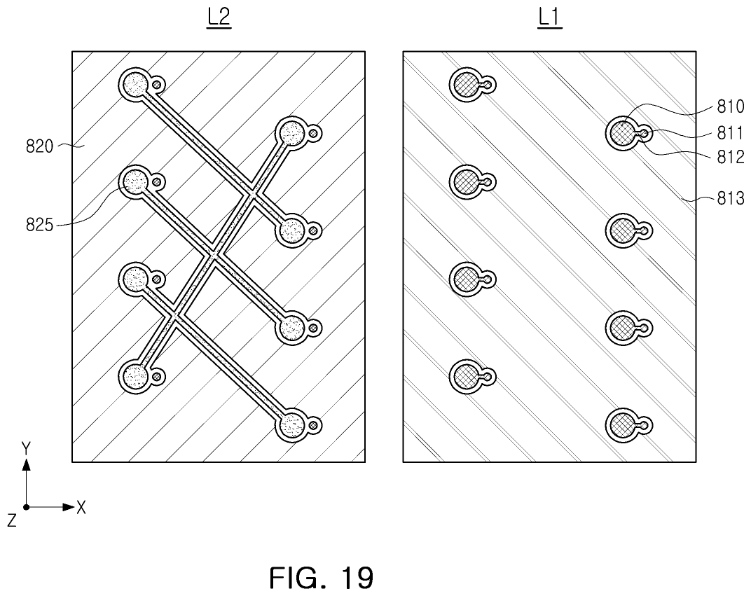

FIG. 19 is a cross-sectional view illustrating a portion of a cross-section of a package substrate according to an example embodiment.

In an example embodiment, the package substrate may have a structure in which a plurality of layers, each layer of the plurality of layers including a respective conductive pattern, are stacked. The plurality of layers may include a first layer including a plurality of pads exposed externally with respect to the package substrate, and a second layer disposed above the first layer. The second layer may include a second conductive pattern 700 connected to a ground voltage, and a floating wiring pattern having an area overlapping the plurality of pads. The plurality of pads may include group pads that transmit the respective data signal groups simultaneously, and the floating wiring pattern may have an area overlapping the respective group pads.

Referring to FIG. 19, DQ signals transmitted through the package substrate may be transmitted as a unit of one data signal group. One data signal group may include eight DQ signals and may be synchronized by one DQS signal.

The second layer L2 included in the package substrate may include a floating wiring pattern 825 having an area overlapping the third group pads. The third group pads may simultaneously transmit the third data signal group. The third data signal group may be synchronized by the third DQS signal. The third data signal group may include eight DQ signals, DQ0, DQ1, DQ2, DQ3, DQ4, DQ5, DQ6, and DQ7.

The second layer L2 may include a floating wiring pattern having an area overlapping respective group pads, for respective group pads that simultaneously transmit one data signal group. Respective group pads have an area overlapping the same floating wiring pattern, and respective group pads and the floating wiring pattern may form capacitance of the same or substantially the same size. In a package substrate where the influence of inductance is dominant, crosstalk noise due to inductance may be reduced by arbitrarily generating capacitance. By adjusting the magnitude of capacitance for each data signal group, an optimal capacitance for significantly reducing crosstalk noise may be implemented.

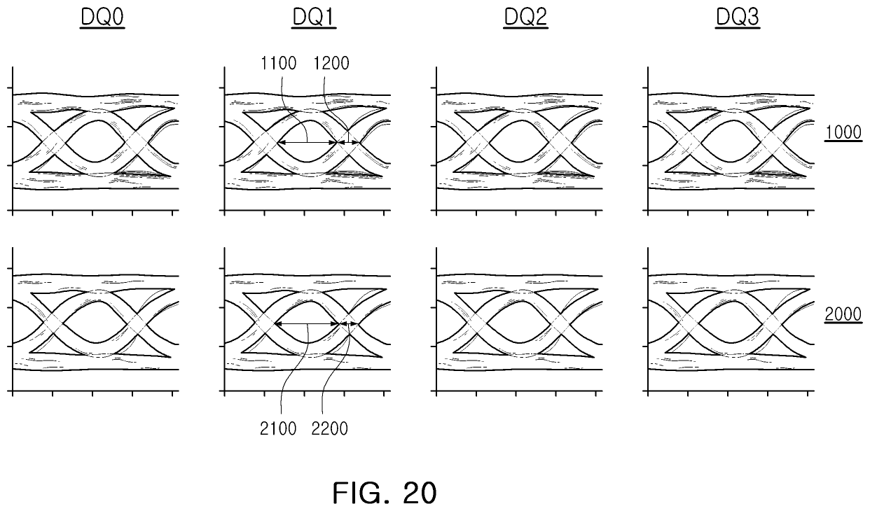

FIG. 20 is a graph illustrating signal transmission characteristics according to an example embodiment.

Referring to FIG. 20, four DQ signals synchronized to one DQS signal may be DQ0, DQ1, DQ2, and DQ3. Graph 1000 may be a graph illustrating signal transmission characteristics transmitted in a package substrate that does not include a floating wiring pattern in the second layer. In a wiring pattern where the influence of inductance is dominant, inductance may cause timing jitter 1200. When timing jitter 1200 occurs, it becomes a limiting factor in increasing the transmission speed of the signal and may reduce the eye margin 1100 of the signal. This may result in degradation of the characteristics of the signal, such as the quality of the signal and the transmission speed of the signal.

Graph 2000 may be a graph illustrating the transmission characteristics of a signal transmitted from a package substrate including a floating wiring pattern in a second layer. Because the second layer includes a floating wiring pattern having an area overlapping a plurality of pads, capacitance may be formed between the floating wiring pattern and the plurality of pads, and between respective adjacent pads. By forming capacitance in a wiring pattern where the influence of inductance is dominant, timing jitter 2200 due to inductance and noise caused by it may be reduced, and the eye margin 2100 may be increased.

Referring to FIG. 20, the timing jitter 2200 of the graph 2000 may be reduced compared to the timing jitter 1200 of the graph 1000, and the eye margin 2100 of the graph 2000 may be increased compared to the eye margin 1100 of the graph 1000. By including a floating wiring pattern in the second layer, the timing jitter may be improved, and the characteristics of the signal transmitted from the package substrate may be improved.

As set forth above, according to some example embodiments, a plurality of layers included in a package substrate may include a first layer on which a plurality of pads exposed externally are disposed, and a second layer located above the first layer and including a floating wiring pattern having an area overlapping the plurality of pads. By forming the floating wiring pattern having an area overlapping the plurality of pads in the second layer, capacitance may be generated between the plurality of pads and the floating wiring, and between respective pads. By forming capacitance in a signal wiring pattern in which the influence of inductance is dominant, inductance may be compensated, and timing jitter occurring when transmitting a high-capacity and/or high-speed signal may be improved, thereby providing a package substrate and a semiconductor package including the same in which crosstalk noise is reduced.

The layers described herein (e.g., layers L) may be considered wiring layers in which the conductive patterns are formed in corresponding base layers. Different patterns of different layers L may be connected by vias to provide wiring to interconnect various ones of the pads (e.g., 315, 325) of the package substrate. These layers L may be separated from one another by dielectric material. It should be appreciated that dielectric material separating adjacent ones of layers L may also form a layer (e.g., an insulating layer) which extends between and contacts the top surface of the layer L below and the bottom surface of the layer L above. These insulating layers may have vias described herein extending therethrough to connect the various conductive patterns of the layers L.

While example embodiments have been illustrated and described above, it will be apparent to those skilled in the art that modifications and variations could be made without departing from the scope of the present inventive concept as defined by the appended claims.

What is claimed is:

1. A package substrate comprising:
a plurality of layers, each layer of the plurality of layers including a corresponding conductive pattern,
wherein the plurality of layers includes,
a first layer including a first conductive pattern and a plurality of pads exposed externally with respect to the package substrate;
a second layer located above the first layer, and including a second conductive pattern and a floating wiring pattern having an area overlapping the plurality of pads; and
a third layer located above the second layer, and including a third conductive pattern.

2. The package substrate of claim 1, wherein the second conductive pattern is connected to a ground voltage.

3. The package substrate of claim 1, further comprising vias extending from the first layer to the third layer and connecting the plurality of pads to the third conductive pattern of the third layer.

4. The package substrate of claim 3, wherein the second conductive pattern includes a plurality of holes through which the vias penetrate.

5. The package substrate of claim 3, wherein the floating wiring pattern is separated from the vias.

6. The package substrate of claim 1, wherein paths of the floating wiring pattern and the third conductive pattern do not completely overlap.

7. The package substrate of claim 1, wherein the floating wiring pattern includes a first floating wiring pattern and a second floating wiring pattern, and portions of the first floating wiring pattern and the second floating wiring pattern overlap.

8. The package substrate of claim 7, wherein a first length of the first floating wiring pattern is longer than a second length of the second floating wiring pattern.

9. The package substrate of claim 7, wherein a first width of the first floating wiring pattern is greater than a second width of the second floating wiring pattern.

10. The package substrate of claim 7, wherein a first gap between the first floating wiring pattern and the second conductive pattern is larger than a second gap between the second floating wiring pattern and the second conductive pattern.

11. The package substrate of claim 7, wherein at least one of the first floating wiring pattern and the second floating wiring pattern is not a straight line.

12. The package substrate of claim 1, wherein the floating wiring pattern includes a terminal portion having an area overlapping a pad of the plurality of pads, and the terminal portion has an area of the same size as a size of the pad.

13. The package substrate of claim 1, wherein the floating wiring pattern includes a terminal portion having an area overlapping a pad of the plurality of pads, and the terminal portion has an area of a smaller size than a size of the pad.

14. The package substrate of claim 1, wherein the floating wiring pattern includes a terminal portion having an area overlapping a pad of the plurality of pads, and the terminal portion has an area of a larger size than the size of the pad.

15. The package substrate of claim 1, wherein the package substrate includes a first package substrate and a second package substrate,
a first material filled between the first layer and the second layer included in the first package substrate is a first dielectric,
a second material filled between the first layer and the second layer included in the second package substrate is a second dielectric, and
a second thickness of the second dielectric is greater than a first thickness of the first dielectric.

16. A semiconductor package comprising:
a main board;
a package substrate;
semiconductor chips mounted on the package substrate; and
a connector connecting the main board to the package substrate,
wherein the package substrate includes a plurality of layers, each layer of the plurality of layers including a corresponding conductive pattern, and
the plurality of layers includes,
a first layer including a first conductive pattern and a plurality of pads exposed externally with respect to the package substrate;
a second layer located above the first layer and including a second conductive pattern and a floating wiring pattern having an area overlapping the plurality of pads; and
a third layer located above the second layer and including a third conductive pattern

17. The semiconductor package of claim 16, wherein the semiconductor package includes a first semiconductor package and a second semiconductor package,
a first material filled between a first floating wiring pattern and the second conductive pattern included in the first semiconductor package is a first dielectric,
a second material filled between a second floating wiring pattern and the second conductive pattern included in the second semiconductor package is a second dielectric, and
the first dielectric and the second dielectric have different dielectric constants.

18. The semiconductor package of claim 17, wherein a fourth gap between the second floating wiring pattern and the second conductive pattern of the second semiconductor package is greater than a third gap between the first floating wiring pattern and the second conductive pattern of the first semiconductor package.

19. The semiconductor package of claim 16, wherein the semiconductor package includes a first semiconductor package and a second semiconductor package, and
a first number of layers of the plurality of layers included in the first semiconductor package is different from a second number of layers of the plurality of layers included in the second semiconductor package.

20. A package substrate comprising:
a plurality of layers, each layer of the plurality of layers including a corresponding conductive pattern,
wherein the plurality of layers includes,
a first layer including a first conductive pattern and a plurality of pads exposed externally with respect to the package substrate;
a second layer located above the first layer, and including a second conductive pattern and a floating wiring pattern having an area overlapping the plurality of pads; and
a third layer located above the second layer, and including a third conductive pattern,
the plurality of pads includes first group pads and second group pads, each of the first group pads and second group pads including four pads simultaneously transmitting four corresponding data signals,
the floating wiring pattern includes a first floating wiring pattern having an area overlapping the first group pads, and a second floating wiring pattern having an area overlapping the second group pads, and
shapes of the first floating wiring pattern and the second floating wiring pattern are different.
